(19) United States
(12) Patent Application Publication
(10) Pub. No.: US 2020/0212871 A1
(43) Pub. Date: Jul. 2, 2020

(54) Apparatus for Antenna Impedance-Matching and Associated Methods

(71) Applicant: Silicon Laboratories Inc., Austin, TX (US)

(72) Inventors: Attila Zolomy, Budapest (HU); Pasi Rahikkala, Vihti (FI)

(21) Appl. No.: 16/237,511

(22) Filed: Dec. 31, 2018

(51) Int. Cl. H03H 7/38; H04B 1/04; H04B 1/18; H01Q 5/335

(52) U.S. Cl. CPC H03H 7/383; H04B 1/0458; H03H 2007/386; H01Q 5/335; H04B 1/18

(57) ABSTRACT

An apparatus includes an impedance matching circuit for matching an impedance of a high quality factor (high-Q) antenna to an impedance of a radio-frequency (RF) circuit. The impedance matching network includes a first reactive network. The impedance matching network also includes a second reactive network coupled in series with the first reactive network. The second reactive network includes a reactive component realized by multiple reactive components so as to reduce sensitivity of the impedance matching network to component tolerances in the second reactive network.

### CROSS-REFERENCE TO RELATED APPLICATIONS

This application is related to U.S. patent application Ser. No. ______, filed on ______ titled “Apparatus with Partitioned Radio Frequency Antenna and Matching Network and Associated Methods,” Attorney Docket No. SILA412. The foregoing application is hereby incorporated by reference in its entirety for all purposes.

### TECHNICAL FIELD

The disclosure relates generally to radio-frequency (RF) apparatus and, more particularly, to apparatus for antenna impedance matching networks or circuits in RF apparatus, and associated methods.

### BACKGROUND

With the increasing proliferation of wireless technology, such as Wi-Fi, Bluetooth, and mobile or wireless Internet of things (IoT) devices, more devices or systems incorporate RF circuitry, such as receivers and/or transmitters. To reduce the cost, size, and bill of materials, and to increase the reliability of such devices or systems, various circuits or functions have been integrated into integrated circuits (ICs). For example, ICs typically include receiver and/or transmitter circuitry.

The RF ICs typically work with circuitry external to the IC to provide a wireless solution. Examples of the external circuitry include baluns, matching circuitry, antennas, filters, switches, and the like.

The description in this section and any corresponding figure(s) are included as background information materials. The materials in this section should not be considered as an admission that such materials constitute prior art to the present patent application.

### SUMMARY

A variety of apparatus and associated methods are contemplated according to exemplary embodiments. According to one exemplary embodiment, an apparatus includes an impedance matching circuit for matching an impedance of a high quality factor (high-Q) antenna to an impedance of an RF circuit. The impedance matching network includes a first reactive network. The impedance matching network also includes a second reactive network coupled in series with the first reactive network. The second reactive network includes a reactive component realized by multiple reactive components so as to reduce sensitivity of the impedance matching network to component tolerances in the second reactive network.

According to another exemplary embodiment, an apparatus includes an impedance matching circuit for matching an impedance of a high-Q antenna to an impedance of an RF circuit. The impedance matching network includes a reactive network. The impedance matching network also includes a resonant network coupled in shunt with the reactive network. A reactance of the resonant tank as a function of frequency varies in an opposite manner of a reactance of the reactive network.

According to another exemplary embodiment, an apparatus includes an impedance matching circuit for matching an impedance of a high-Q antenna to an impedance of an RF circuit. The impedance matching network includes a reactive network. The impedance matching network also includes a resonant network coupled in series with the reactive network. A reactance of the resonant tank as a function of frequency varies in an opposite manner of a reactance of the reactive network.

### BRIEF DESCRIPTION OF THE DRAWINGS

The appended drawings illustrate only exemplary embodiments and therefore should not be considered as limiting the scope of the application or of the claimed subject-matter. Persons of ordinary skill in the art will appreciate that the disclosed concepts lend themselves to other equally effective embodiments. In the drawings, the same numeral designators used in more than one drawing denote the same, similar, or equivalent functionality, components, or blocks.

FIG. 1 shows a circuit arrangement for an RF communication system according to an exemplary embodiment.

FIG. 2 shows a circuit arrangement for an RF communication system according to an exemplary embodiment.

FIG. 3 shows a circuit arrangement for an RF communication system according to an exemplary embodiment.

FIGS. 4A-4I show conventional antenna matching networks.

FIG. 5 shows a circuit arrangement for antenna matching circuitry according to an exemplary embodiment.

FIGS. 6A-6F show circuit arrangements for reactive networks used in antenna matching circuitry according to exemplary embodiments.

FIGS. 7A-7B show circuit arrangements for reactive networks used in antenna matching circuitry according to exemplary embodiments.

FIG. 8 shows a circuit arrangement for antenna matching circuitry according to an exemplary embodiment.

FIGS. 9A-9C show circuit arrangements for reactive networks used in antenna matching circuitry according to exemplary embodiments.

FIG. 10 shows a circuit arrangement for a reactive network used in antenna matching circuitry according to an exemplary embodiment.

FIG. 11 shows a circuit arrangement for a reactive network used in antenna matching circuitry according to an exemplary embodiment.

FIGS. 12A-12C show circuit arrangements for reactive networks used in antenna matching circuitry according to exemplary embodiments.

FIGS. 13A-13C show circuit arrangements for reactive networks used in antenna matching circuitry according to exemplary embodiments.

FIGS. 14A-14C show circuit arrangements for reactive networks used in antenna matching circuitry according to exemplary embodiments.

FIG. 15 shows a circuit arrangement for a reactive network used in antenna matching circuitry according to an exemplary embodiment.

FIG. 16 shows a circuit arrangement for a reactive network used in antenna matching circuitry according to an exemplary embodiment.

FIGS. 17A-17C show circuit arrangements for resonant networks used in antenna matching circuitry according to exemplary embodiments.

FIG. 18 shows a circuit arrangement for antenna matching circuitry according to an exemplary embodiment.

FIGS. 19A-19C show circuit arrangements for resonant networks used in antenna matching circuitry according to exemplary embodiments.

### DETAILED DESCRIPTION

The disclosure relates generally to RF apparatus and, more particularly, to apparatus for impedance matching circuits (or matching circuits or matching networks or matching circuitry or impedance matching networks or impedance matching circuitry) in RF apparatus, and associated methods. As persons of ordinary skill in the art will understand, impedance matching circuits may be called simply “matching circuits” without loss of generality.

Impedance matching or impedance transformation circuits, here called matching circuits, are typically used in RF apparatus, such as receivers, transmitters, and/or transceivers, to provide an interface or match between circuitry that have different impedances.

More specifically, in the case of purely resistive impedances, maximum power transfer takes place when the output impedance of a source circuit equals the input impedance of a load circuit. In the case of complex impedances, maximum power transfer takes place when the input impedance of the load circuit is the complex conjugate of the output impedance of the source circuit.

As an example, consider an antenna with a 50-ohm impedance (R=50 n) coupled to a receive or receiver (RX) circuit with a 50-ohm impedance. In this case, maximum power transfer takes place without the user of an impedance matching circuit because the output impedance of the antenna equals the input impedance of the RX circuit.

Now consider the situation where an antenna with a 50-ohm impedance (R=50Ω) coupled to an RX circuit with a 250-ohm impedance. In this case, because the respective impedances of the antenna and the RX circuit are not equal, maximum power transfer does not take place.

Use of an impedance matching circuit, however, can match the impedance of the antenna to the impedance of the RX circuit. As a result of using the impedance matching circuit, maximum power transfer from the antenna to the RX circuit takes place.

More specifically, the impedance matching circuit is coupled between the antenna and the RX circuit. The impedance matching circuit has two ports, with one port coupled to the antenna, and another port coupled to the RX circuit, respectively.

At the port coupled to the antenna, the impedance matching circuit ideally presents a 50-ohm impedance to the antenna. As a result, maximum power transfer takes place between the antenna and the impedance matching circuit.

Conversely, at the port coupled to the RX circuit, the impedance matching circuit presents a 250-ohm impedance to the RX circuit. Consequently, maximum power transfer takes place between the impedance matching circuit and the RX circuit.

In practice, the impedance matching circuit often fails to perfectly match the impedances. In other words, signal transmission from one network to another is not perfect and 100% of the signal power is not transmitted. As a result, reflection occurs at the interface between circuits or networks with imperfectly matched impedances.

The reflection coefficient, S11, may serve as one measure or figure of merit for the level of impedance matching. A lower S11 denotes better power transmission (better impedance matching), and vice-versa.

In exemplary embodiments, impedance matching circuits or apparatus including impedance matching circuits, and associated methods are disclosed. The impedance matching circuits are relatively low cost, may be used with RF receivers (RX), RF transmitter (TX), and/or RF transceivers.

Furthermore, impedance matching circuits according to various embodiments may be adapted to various operating frequency ranges, power levels, and RX circuit or RX and TX circuit impedances. In addition, impedance matching circuits according to various embodiments may be used with a variety of RX or RX and TX circuit configurations (e.g., low-IF receivers, direct conversion receivers or transmitters, etc.), as persons of ordinary skill in the art will understand.

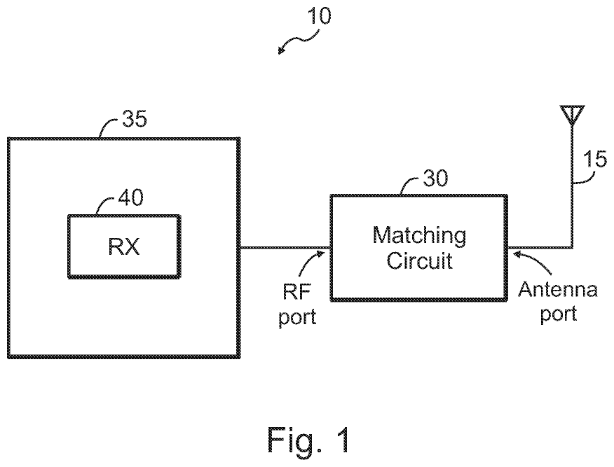

FIG. 1 shows a circuit arrangement for an RF communication system 10 according to an exemplary embodiment. The embodiment in FIG. 1 shows an RF apparatus 35 that has RX functionality, i.e., includes receiver (RX) circuitry 40.

RF communication system 10 includes matching circuit 30. Matching circuit 30 has an antenna port and an RF port. The antenna port of matching circuit 30 is coupled to antenna 15. The RF port of matching circuit 30 is coupled to RF apparatus 35. Antenna 15 receives RF signals, and provides the received signals to matching circuit 30 via the antenna port. In exemplary embodiments, antenna 15 has a relatively high quality factor (Q), i.e., the antenna is a high-Q antenna, as is commonly known.

The RF signals provided by the RF port of matching circuit 30 are provided to receiver or receive (RX) circuitry 40. Matching circuit 30 matches the impedance of antenna 15 to the impedance of RX circuitry 40. Thus, matching circuit 30 according to exemplary embodiments accommodates the high-Q nature of antenna 15. Details of matching circuit 30 and various embodiments of it are described in detail below.

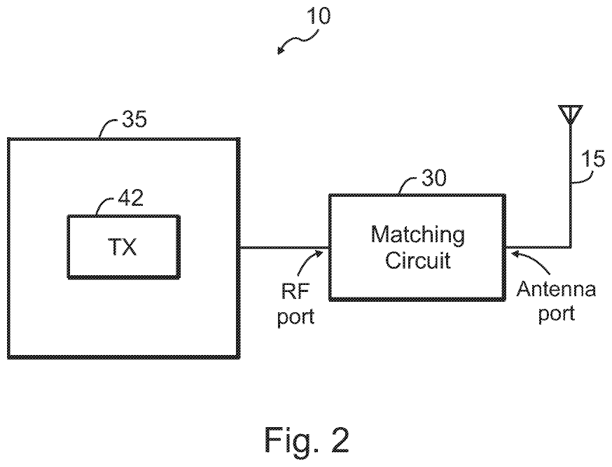

FIG. 2 shows a circuit arrangement for an RF communication system 10 according to an exemplary embodiment. The embodiment in FIG. 2 shows an RF apparatus 35 that has TX functionality, i.e., transmitter or transmit (TX) circuitry 42.

RF communication system 10 includes matching circuit 30. Matching circuit 30 has an antenna port and an RF port. The antenna port of matching circuit 30 is coupled to antenna 15. The RF port of matching circuit 30 is coupled to RF apparatus 35. RF apparatus 35, by using TX circuitry 42, generates RF signals, and via matching circuit 30 provides the RF signals to antenna 15 for transmission into a medium, such as the atmosphere, vacuum, etc.

More specifically, TX circuitry 42 generates RF signals that RF apparatus 35 provides to the RF port of matching circuit 30. In exemplary embodiments, antenna 15 has a relatively high quality factor (Q), i.e., the antenna is a high-Q antenna, as is commonly known.

The antenna port of matching circuit 30 is coupled to antenna 15. Matching circuit 30 matches the impedance of antenna 15 to the impedance of TX circuitry 42. Thus, matching circuit 30 according to exemplary embodiments accommodates the high-Q nature of antenna 15. Details of matching circuit 30 and various embodiments of it are described in detail below.

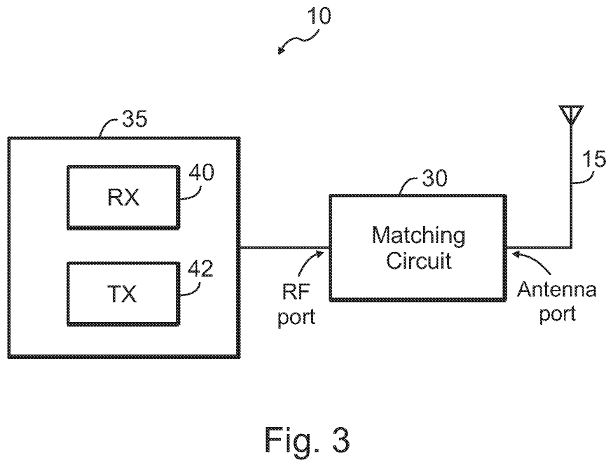

FIG. 3 shows a circuit arrangement for an RF communication system 10 according to an exemplary embodiment. The embodiment in FIG. 3 shows an RF apparatus 35 that includes a transceiver or transceiver circuitry in that it that has both RX and TX functionality, i.e., includes both RX circuitry 40 and TX circuitry 42.

RF communication system 10 includes matching circuit 30. Matching circuit 30 has an antenna port and an RF port. The antenna port of matching circuit 30 is coupled to antenna 15. The RF port of matching circuit 30 is coupled to RF apparatus 35.

In the receive (RX) mode, antenna 15 receives RF signals, and provides the received signals to matching circuit 30 via the antenna port. In exemplary embodiments, antenna 15 has a relatively high quality factor (Q), i.e., the antenna is a high-Q antenna, as is commonly known.

The RF signals provided by the RF port of matching circuit 30 are provided to receiver or receive (RX) circuitry 40. Matching circuit 30 matches the impedance of antenna 15 to the impedance of RX circuitry 40. Thus, matching circuit 30 according to exemplary embodiments accommodates the high-Q nature of antenna 15. Details of matching circuit 30 and various embodiments of it are described in detail below.

In the transmit mode, RF apparatus 35, by using TX circuitry 42, generates RF signals, and via matching circuit 30 provides the RF signals to antenna 15 for transmission into a medium, such as the atmosphere, vacuum, etc.

More specifically, TX circuitry 42 generates RF signals that RF apparatus 35 provides to the RF port of matching circuit 30. In exemplary embodiments, antenna 15 has a relatively high quality factor (Q), i.e., the antenna is a high-Q antenna, as is commonly known.

The antenna port of matching circuit 30 is coupled to antenna 15. Matching circuit 30 matches the impedance of antenna 15 to the impedance of TX circuitry 42. Thus, matching circuit 30 according to exemplary embodiments accommodates the high-Q nature of antenna 15. Details of matching circuit 30 and various embodiments of it are described in detail below.

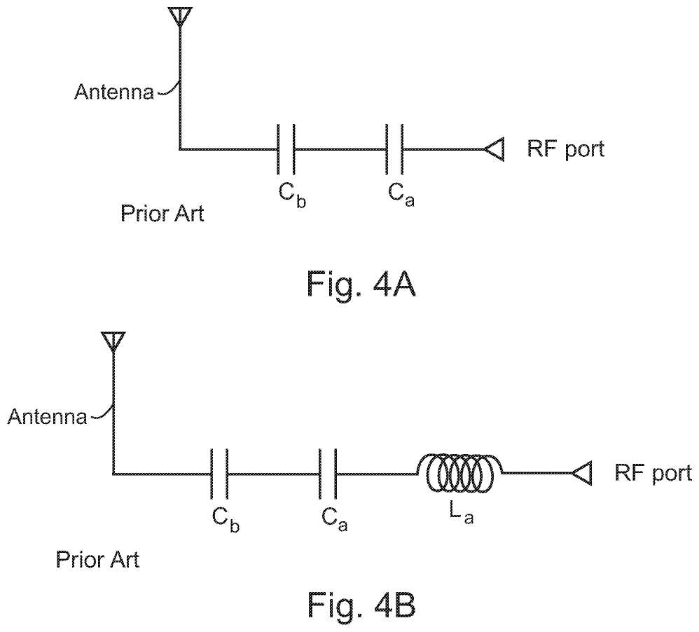

Conventional matching circuits are known to persons of ordinary skill in the art. FIGS. 4A-4I show examples of conventional matching circuits. The various matching circuits in FIGS. 4A-4I use one or more capacitors (C) and/or one or more inductors (L), in various configurations, such as series and shunt.

For example, FIG. 4A shows a conventional series matching circuit that includes two capacitors. As another example, FIG. 4B shows a conventional series matching circuit that adds an inductor to the circuit of FIG. 4A, whereas FIG. 4C replaces one of the capacitors in FIG. 4B with an inductor.

Conversely, FIG. 4D shows a shunt configuration that uses two capacitors. FIG. 4E shows a shunt configuration in which the shunt capacitor in FIG. 4D is replaced with an inductor. FIGS. 4F-4I illustrate configurations that use shunt and series components.

As noted above, matching circuits according to exemplary embodiments provide impedance matching for high-Q antennas. High-Q antenna impedances typically have five or more times higher imaginary parts than real parts. Thus, if one represents the antenna impedance as Z=R+jQ, where R and Q represent, respectively, the real and imaginary parts of the impedance Z, then for high-Q antennas, Q is significantly higher (five times or more) than R (e.g., Q>R or Q>>R).

The imaginary part of the impedance of a high-Q antenna can be inductive or capacitive. In other words, a high-Q antenna with an inductive imaginary part constitutes an inductive high-Q antenna. Conversely, a high-Q antenna with a capacitive imaginary part constitutes a capacitive high-Q antenna.

Owing to the relativel magnitures of the real and imaginary parts, the impedance locust of high-Q antennas is situated at or near the edge of a Smitth chart. For inductive high-Q antennas, the locust is in the upper half of the Smith Chart, whereas for capacitive high-Q antenna, the locust is in the lower half of the Smith Chart.

In both cases, because of the high-Q nature of the antenna, the phase of the reflection decreases as a function of frequency (frequency of the RF signal that the antenna transmits or receives), i.e., it rotates clockwise with the frequency on the Smith chart. A possible simple way to match these antennas is to use series capacitors or series inductors.

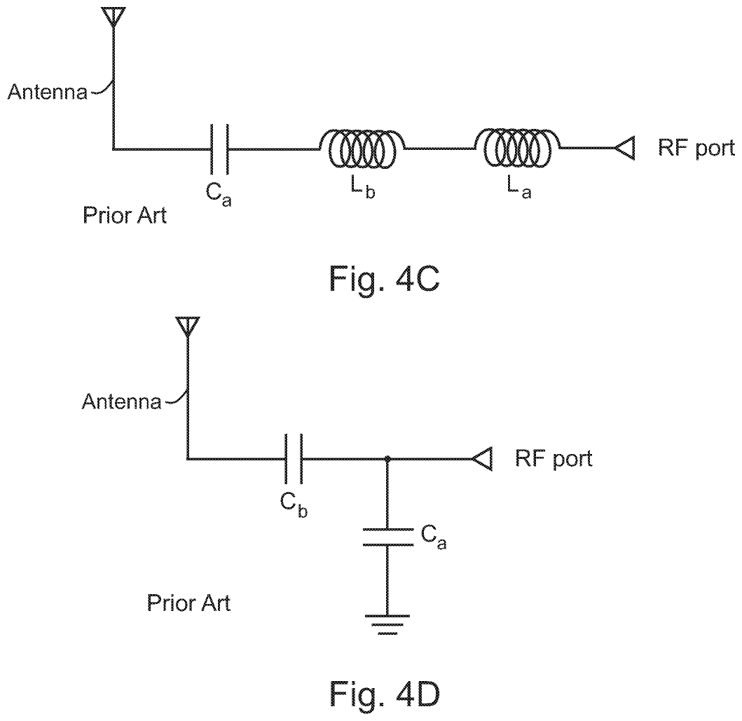

One aspect of the disclosure relates to matching circuits that include two cascade-coupled reactive networks. FIG. 5 shows a circuit arrangement for antenna matching circuitry according to an exemplary embodiment. More specifically, matching circuit 30 in FIG. 5 includes reactive network 45 coupled in series or cascade with reactive network 55. Reactive networks 45 and 55, as the name suggests, include one or more inductors and/or capacitors.

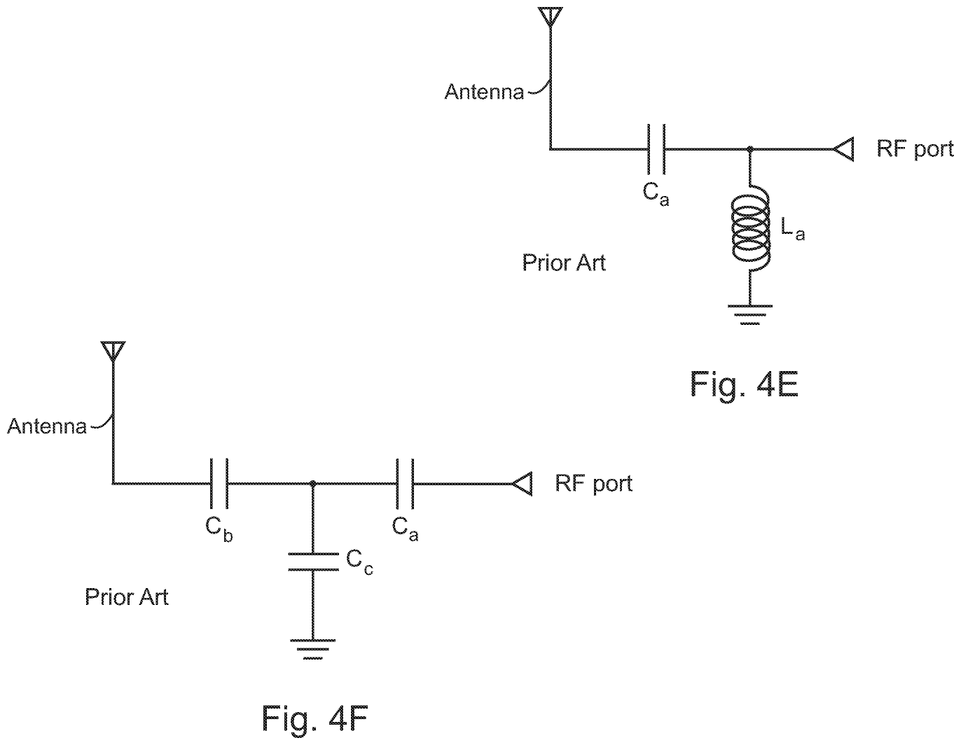

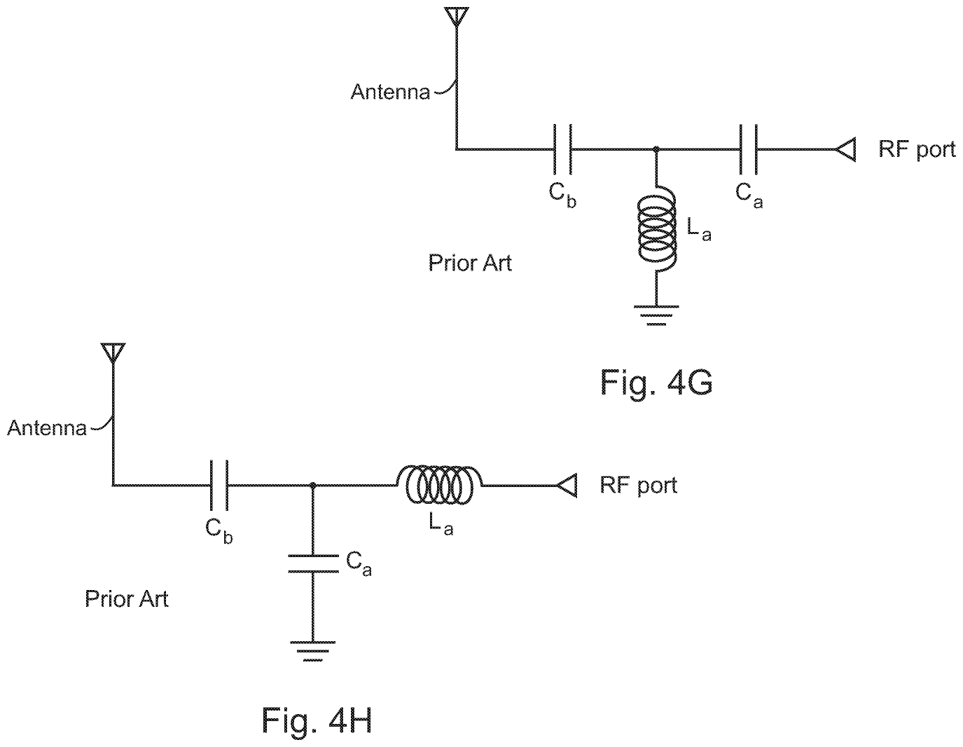

FIGS. 6A-6F and FIGS. 7A-7B show, respectively, circuit arrangements according to exemplary embodiments for reactive network 45 and reactive network 55, respectively. More specifically, by coupling in series (as shown in FIG. 5) one of reactive networks 45 in FIGS. 6A-6F with one of reactive networks 55 in FIGS. 7A-7B, a matching network 30 may be realized. Such matching networks 30 may be used to match the impedance of RF circuitry with high-Q antennas, as described above.

Referring to FIG. 6A, reactive network 45 includes a capacitor C1, coupled between the input and output nodes of reactive network 45 and ground. Conversely, FIG. 6B shows an inductor L1, coupled between the input and output nodes of reactive network 45 and ground. FIGS. 6C-6F include two reactive components, e.g., two capacitors, two inductors, or one capacitor and one inductor.

Due to the high-Q nature of the antenna, the matching provided by conventional matching circuits is relatively sensitive to capacitance variations when a single capacitor is used. To remedy this situation, in exemplary embodiments, two or more series-coupled capacitors are used, with increased capacitance values (to compensate for the reduction of overall capacitance when capacitors are coupled in series) to increases the capacitor values. Higher capacitor values (i.e., capacitors with higher capacitance values) in a multiple series-coupled capacitor chain (i.e., cascade-coupled) gives smaller relative (in percentage) technological spreading, or variations in the capacitance values, for each capacitor as the absolute tolerance of the capacitors are fixed (e.g., ±0.05 pF). Besides, the independent statistical behaviour of the capacitor elements in the chain or cascade reduce the probabilty of the occurence of worst case scenarios. Moreover, the higher capacitor values decreases the effects of any possible unwanted parasitic (e.g., printed circuit board (PCB) or shielding frindging field capacitance) and its spreading.

Thus, in exemplary embodiments, two or more capacitors are used to reduce the technological spreading discussed above. More specifically, FIGS. 7A-7B, as noted above, show reactive network 55 according to embodiments. FIG. 7A shows two capacitors, C1 and C2, coupled in series. Conversely, FIG. 7B shows a set of capacitors, C1-Cn, coupled in series, where n represents a positive integer greater than two.

By using two or more capacitors, rather than a single capacitor, the variation in the overall capacitance realized the combination of the multiple capacitors (generally, C1-Cn) due to the tolerances of the individual capacitors is reduced. As a result, matching circuits 30 (see FIG. 5) provide improved impedance matching with high-Q antennas.

In various embodiments, any of reactive networks 45 may be combined with any of the reactive networks 55 to realize matching circuits 30 (see FIG. 5). For example, reactive network 45 in FIG. 6A (which includes a shunt capacitor, i.e., a capacitor coupled in a shunt fashion, between an internal node of reactive network 45 and ground) with reactive network 55 in FIG. 7A (which includes two series-coupled capacitors). As another example, reactive network 45 in FIG. 6B (which includes a shunt inductor, i.e., a inductor coupled in a shunt fashion, between an internal node of reactive network 45 and ground) with reactive network 55 in FIG. 7A.

As another example, reactive network in FIG. 6C (which includes series-coupled capacitor C1 and shunt-coupled capacitor C2) with reactive network 55 in FIG. 7B. Other embodiments may be realized by combining a desired reactive network 45 from FIGS. 6A-6F with another reactive desired reactive network from FIGS. 7A-7B. The possible combinations of reactive networks 45 and reactive networks 55 provide matching circuits 30 for a variety of applications (e.g., various antennas with their particular characteristics, various operating frequencies, various overall costs, various overall performance characteristics, etc.).

Note that the values of the components in matching circuits according to various embodiments depend on a variety of factors, as posas will understand. Examples include operating frequency (RF frqeuency), type of antenna (impedance, whether capacitive or inductive), type of RF circuit (impedance, etc.), and the like, as posas will understand. In some embodiments, if the operating frequency is sufficiently high, for example, some of the components may be realized using parasitic elements, for example, parasitic capacitance or inductance of a printed-circuit board (or other substrate) in which the various circuits are formed or to which the various circuits are attached or physically connected (e.g., soldered).

The embodiments described above, i.e., reactive circuits 45 in FIGS. 6A-6F and reactive circuits 55 in FIGS. 7A-7B, are typically suitable for use with high-Q inductive antennas (the antenna impedance has an inductive value, or the inductive component of the antenna impedance dominates the capacitive component). Variations may be made to the embodiments to make them suitable for use with capacitive antennas (the antenna impedance has a capacitive value, or the capacitive component of the antenna impedance dominates the inductive component).

More specifically, to realize matching circuits 30 for high-Q capacitive antennas, referring to FIGS. 6A-6F, the series capacitors (e.g., C1 in FIG. 6C, C1 in FIG. 6D) are replaced with one or more (one or more) series-coupled inductors. Conversely, inductors (e.g., L1 in FIG. 6E, L1 in FIG. 6F) are replaced with (one or more) series-coupled inductors.

Thus, matching circuits 30 for capacitive high-Q antennas may be realized by making such modifications, and combining the resulting reactive networs 45 with reactive networks 55, as described above. Various combinations of reactive networs 45 with reactive networks 55 (i.e., by coupling them in series, as described above) may thereofore be used in various embodiments to realize a variety of matching circuits 30 for capacitive high-Q antennas.

Note that, if the real part or component of the antenna's impedance is close to the nominal impedance, say 50 ohms, or if the shunt parasitics inherently push the real impedance to 50 ohms (or about 50 ohms), then the shunt elements may be omitted. Otherwise, shunt elements, which include either a single reactive component (C, L) or multiple shunt elements (multiple Ls or multiple Cs) may be used, as described above.

For example, inductor L1 in FIG. 6B or 6D, or inductor L2 in FIG. 6F may be implemented by multiple inductors coupled in parallel with one another. As another example, capacitor C1 in FIG. 6A or 6E, or capacitor C2 in FIG. 6C may be implemented by multiple capacitors couopled in parallel with one another.

Thus, a variety of matching circuits 30 can be generated by spliting the shunt reactive elements or components to more than one reactive component. Doing so reduces the effect of component variability or tolerance, as described above.

Another aspect of the disclosure relates to impedance matching circuits for high-Q antennas, where the matching circuits have relatively high bandwidth, i.e., are wideband matching circuits. More specifically, wideband matching circuits provide impedance matching with high-Q antennas over a wider frequency range than do non-wideband or relatively narrowband matching circuits (e.g., as described above).

The bandwidth of the matching circuits according to various embodiments can be increased by adding resonators (resonant networks) that have the opposite reactance variation than the matching circuit otherwise has around the resonance frequency of the resonant networks. The bandwidth of the matching circuit depends on the quality factor (Q) of the antenna. For antennas in exemplary embodiments, with a Q of 11, for example, the −3 dB relative bandwidth (to the band center frequency) is approximately 9%, and the −10 dB bandwidth is approximately 2.5%. By adding proper resonators, the −10 dB relative bandwidth can be increased from 2.5% to approximately 3%.

Matching circuits with series resonant behavior exhibit capacitive impedance below, and inductive impedance above, the resonant frequency, respectively, at the RF ports of the matching circuits. The resonant frequency is typically the middle frequency of the RF band of interest. An additional shunt-coupled parallel resonant tank at the RF port behaves in the opposite manner, i.e., it exhibits an inductive impedance below, and a capacitive impedance above, respectively, the same resonant frequency. By coupling the series resonant behaving matching circuit with the parallel resonant tank, the opposite changes of their reactances compensate or cancel each other to some extent. Doing so realizes or produces a wideband matching circuit for high-Q antennas.

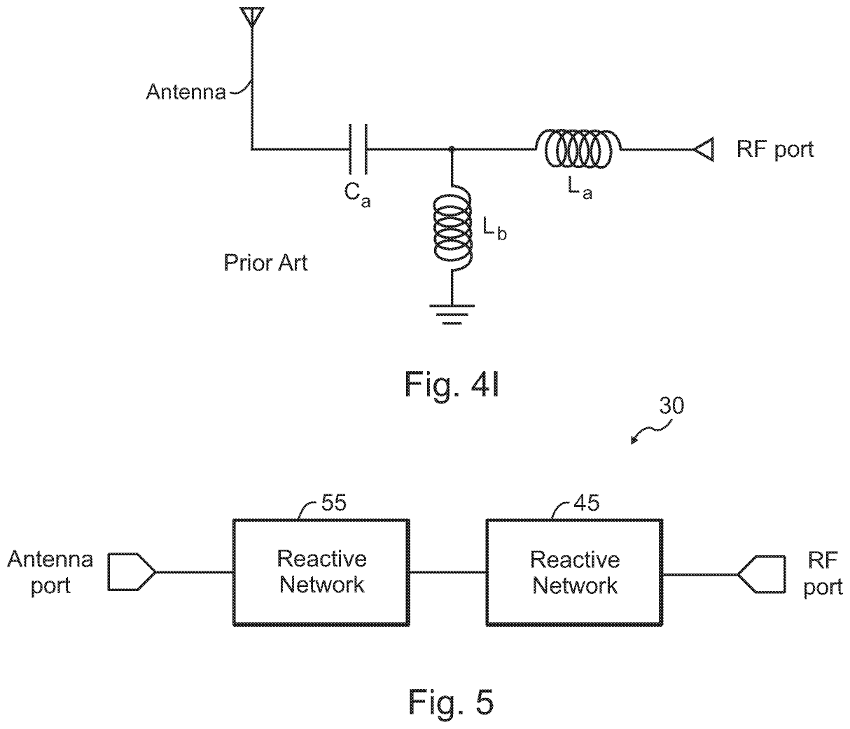

In some embodiments, a shunt resonant network is used in matching networks. FIG. 8 shows a matching network 30 that uses this configuration. More specifically, matching circuit 30 in FIG. 8 includes resonant network 50 coupled in shunt with the RF port, i.e., between the RF port and ground.

Resonant network 50 is also coupled to reactive network 55. Reactive network 45 is coupled in series or cascade with the antenna port of matching circuit 30. Resonant networks 50, as the name suggests, include one or more inductors coupled to one or more respective capacitors to form a resonant circuit or tank or network.

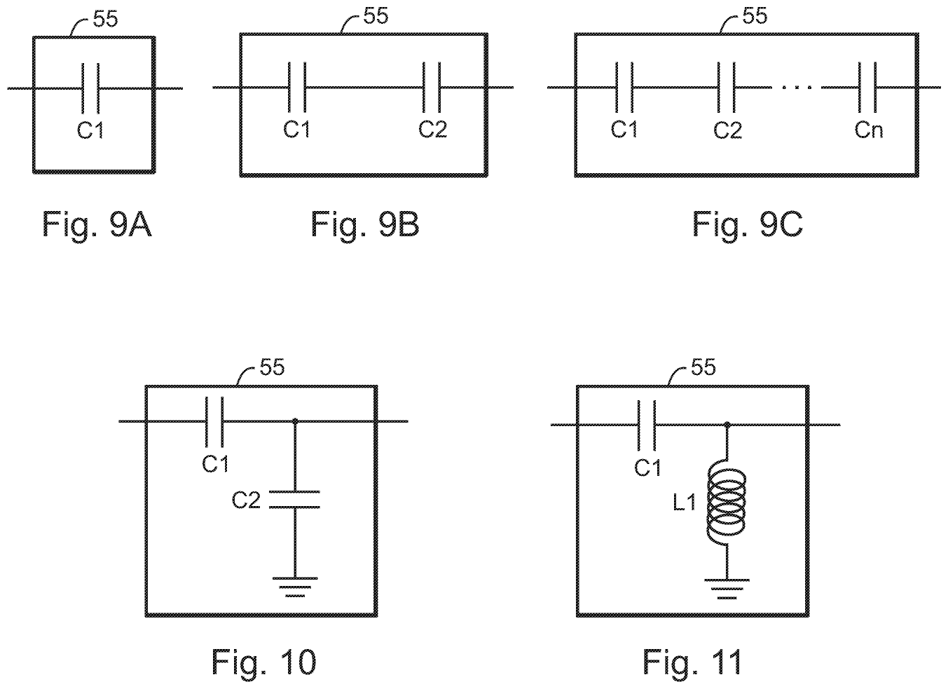

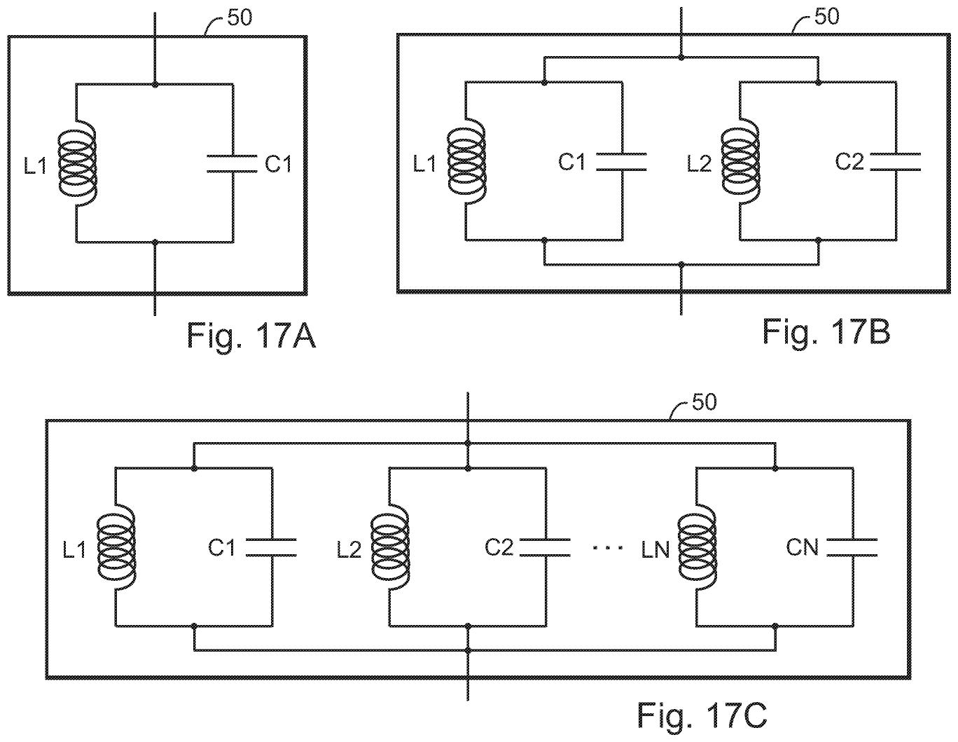

FIGS. 12A-12C, 13A-13C, 14A-14C, 15, and 16 show circuit arrangements with parallel resonant behavior according to exemplary embodiments for reactive network 55. FIGS. 17A-17C show, respectively, circuit arrangements according to exemplary embodiments for resonant networks 50.

More specifically, by coupling (as shown in FIG. 8) one of reactive networks 55 in FIGS. 12A-12C, 13A-13C, 14A-14C, 15, and 16 with one of resonant networks 50 in FIGS. 17A-17C, a wideband matching network 30 may be realized. Such matching networks 30 may be used to match the impedance of RF circuitry with high-Q antennas, as described above.

In FIG. 12A, an additional capacitor is used to form a T-configuration. The additional capacitor, C1, may be split into multiple series-coupled capacitors to reduce sensitivity to component tolerance (of the unsplit capacitor). Thus, FIG. 12B shows an exemplary embodiment that is obtained by splitting C1 in FIG. 12A with two series-coupled capacitors CIA and C1B. Similarly, FIG. 12C shows an exemplary embodiment that is obtained by splitting C1 in FIG. 12A with N series-coupled capacitors C1A-C1N, where N is a positive integer greater than two.

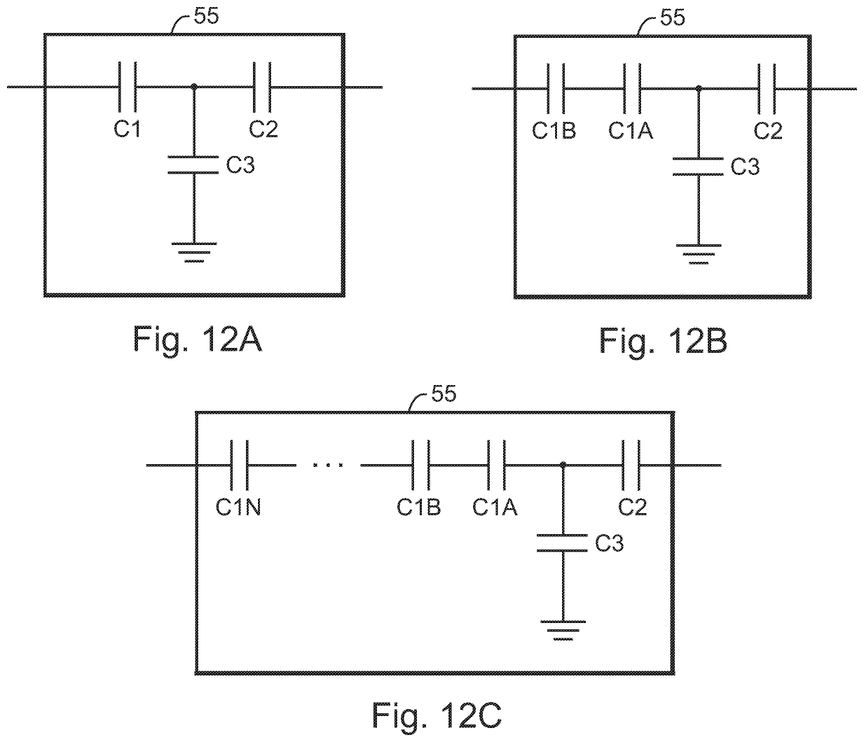

The embodiments in FIGS. 13A-13C are similar to reactive networks 55 in FIGS. 12A-12C, respectively. In reactive networks 55 in FIGS. 13A-13C, however, a shunt inductor L1 is used, rather than a shunt capacitor, as is the case in FIGS. 12A-12C.

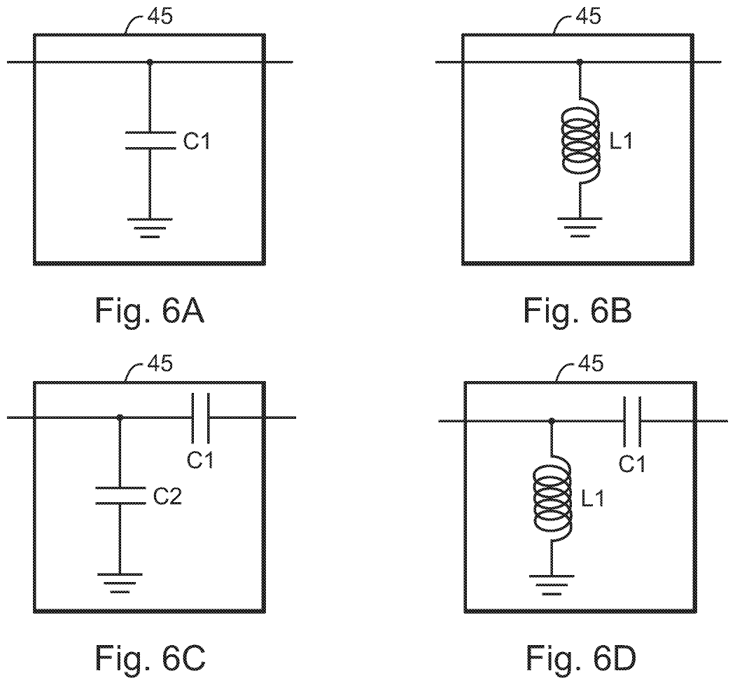

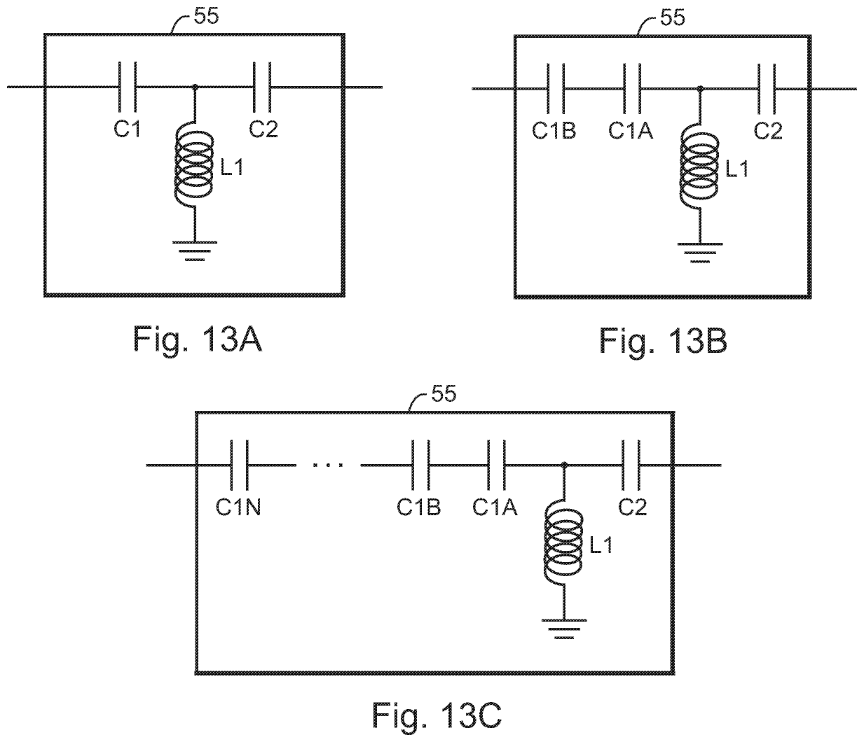

The embodiments in FIGS. 14A-14C are similar to the embodiments in FIGS. 9A-9C, respectively. Instead of one or more series-coupled capacitors, as is the case in FIGS. 9A-9C, reactive networks 55 in FIGS. 14A-14C use one or more inductors. In the case of multiple inductors, the inductors are coupled in series (or, put another way, a single inductor is split into multiple inductors) to reduce sensitivity of the impedance matching to component tolerances, as described above.

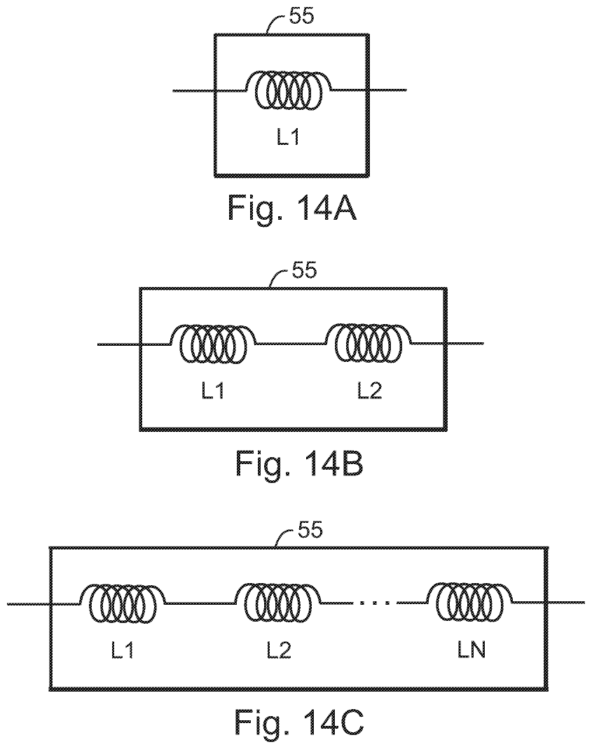

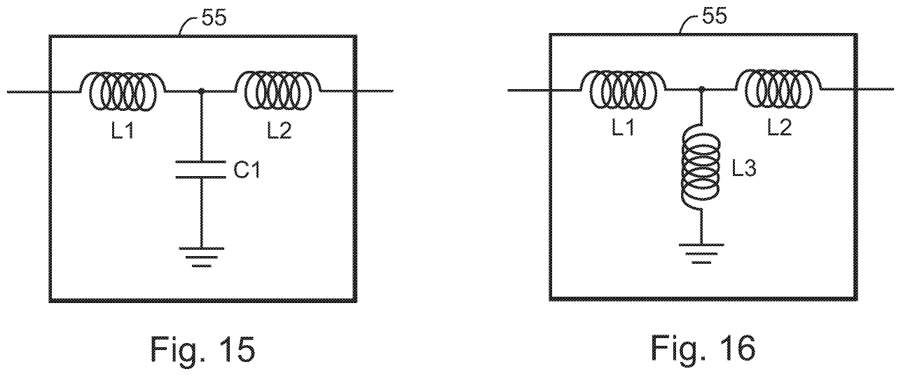

In the embodiments in FIGS. 15 and 16, series-coupled inductors L1 and L2 are used in a T-configuration. In FIG. 15, capacitor C1 is used in addition to the inductors L1 and L2. In the embodiment in FIG. 16, however, an additional inductor L3 is used in addition to the inductors L1 and L2. Each of inductors in FIGS. 15 and 16 may be split into multiple inductors, similar to the splitting shown in FIGS. 14A-14C.

FIGS. 17A-17C show the details of resonant network 50 (see FIG. 8). Referring to FIG. 17A, a parallel resonant network is shown, which includes inductor L1 in parallel with capacitor C1. In FIG. 17B, two parallel resonant networks (L1∥C1 (i.e., L1 coupled in parallel with C1) and L2∥C2) are coupled in parallel. By splitting a single parallel resonant network into two parallel networks, sensitivity to component tolerances is reduced, as described above.

In FIG. 17C, N parallel networks (L1∥C1, L2∥C2, . . . , LN∥CN) are used, where N represents a positive integer greater than two. By splitting a single parallel resonant network into N parallel networks, sensitivity to component tolerances is reduced, as described above. Note that, rather than splitting both the capacitor and the inductor in the resonant tank or tank into multiple capacitors or inductors, in some embodiments, either the capacitor or the inductor may be split into multiple capacitors or inductors, respectively, as desired.

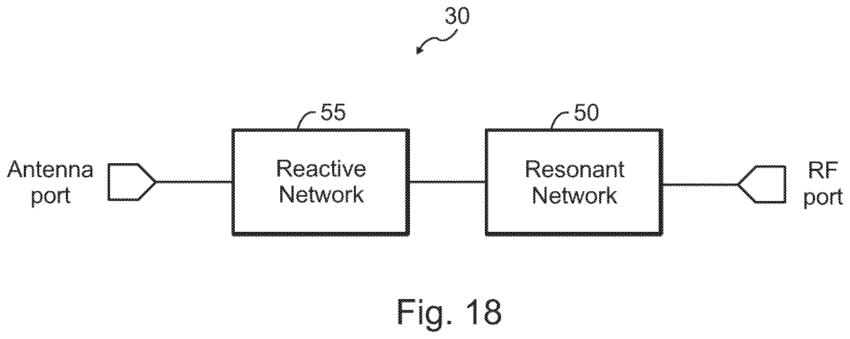

In some embodiments, a series resonant network is used in matching networks. FIG. 18 shows a matching network 30 that uses this configuration. More specifically, matching circuit 30 in FIG. 18 includes resonant network 50 coupled in series with reactive network 55. Resonant networks 50, as the name suggests, include one or more inductors coupled to one or more respective capacitors to form a resonant circuit or tank or network.

A matching circuit with parallel resonant behavior exhibits inductive impedance below, and capacitive above, respectively, the resonant frequency at the RF port. The resonant frequency is typically the middle frequency of the RF band of interest. An additional series connected series resonant tank at the RF port behaves in the opposite manner, i.e., it exhibits capacitive impedance below, and inductive impedance above, respectively, the same resonant frequency. By coupling the series behaving matching circuit with the parallel resonant tank, the opposite changes of their reactances compensate or cancel each other to some extent. Doing so realizes or produces a wideband matching circuit for high-Q antennas.

As FIG. 18 shows, matching circuits 30 that use a series resonant tank include reactive network 55. FIGS. 9A-9C, 10, and 11 show circuit arrangements according to exemplary embodiments for reactive network 55. Reactive networks 55 shown in those figures are described in detail above.

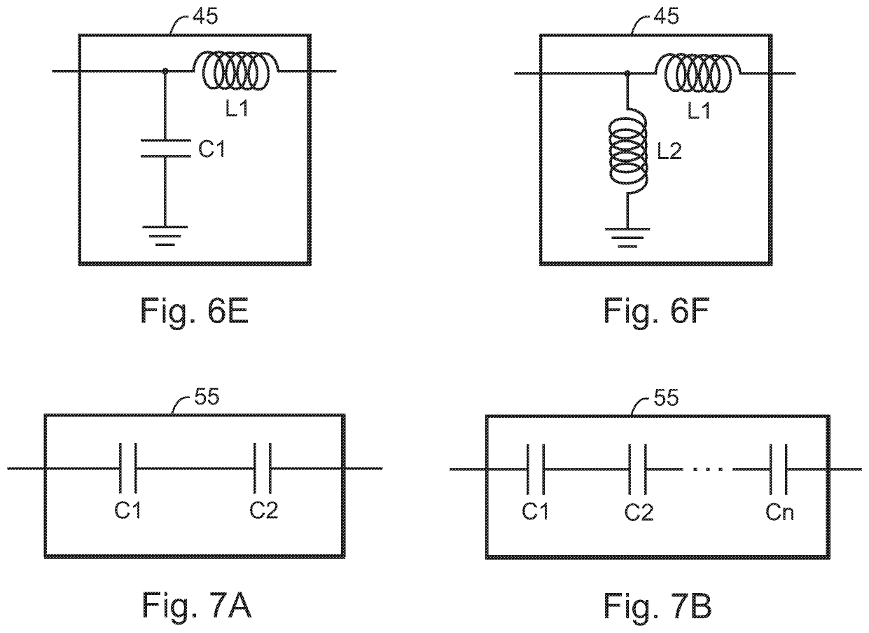

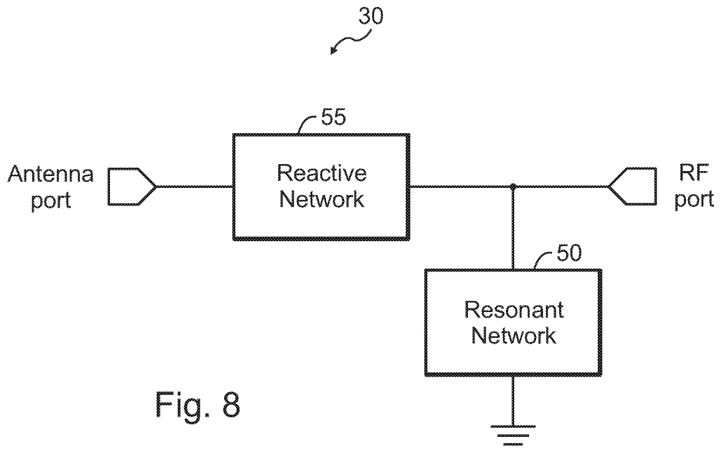

Referring to FIGS. 9A-9C, reactive network 55 includes one or more capacitors. In the case of multiple capacitors, the capacitors are coupled in series (or, put another way, a single capacitor is split into multiple capacitors) to reduce sensitivity of the impedance matching to component tolerances, as described above. In FIGS. 10 and 11, a shunt capacitor (FIG. 10) or a shunt inductor (FIG. 11) is added.

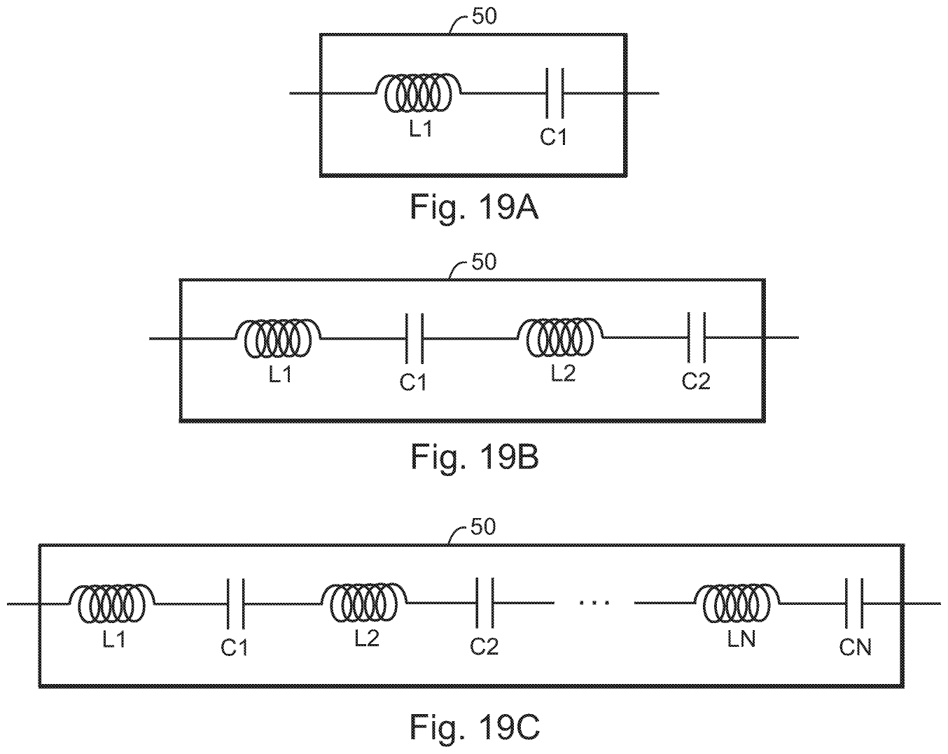

As FIG. 18 shows, matching circuit 30 also includes series resonant network 50. FIGS. 19A-19C show the details of resonant network 50 (see FIG. 18). Referring to FIG. 19A, a series resonant network is shown, which includes inductor L1 in series with capacitor C1. In FIG. 19B, two series resonant networks (L1-C1 (i.e., L1 coupled in series with C1) and L2-C2) are coupled in series. By splitting a single series resonant network into two series networks, sensitivity to component tolerances is reduced, as described above.

In FIG. 19C, N series networks (L1-C1, L2-C2, . . . , LN-CN) are used, where N represents a positive integer greater than two. By splitting a single series resonant network into N series networks, sensitivity to component tolerances is reduced, as described above. Note that, rather than splitting both the capacitor and the inductor in the resonant tank into multiple capacitors or inductors, in some embodiments, either the capacitor or the inductor may be split into multiple capacitors or inductors, respectively, as desired.

By coupling (as shown in FIG. 18) one of reactive networks 55 in FIGS. 9A-9C, 10, and 11 with one of resonant networks 50 in FIGS. 19A-19C, a wideband matching network 30 may be realized. Such matching networks 30 may be used to match the impedance of RF circuitry with high-Q antennas, as described above.

Referring to the figures, persons of ordinary skill in the art will note that the various blocks shown might depict mainly the conceptual functions and signal flow. The actual circuit implementation might or might not contain separately identifiable hardware for the various functional blocks and might or might not use the particular circuitry shown. For example, one may combine the functionality of various blocks into one circuit block, as desired. Furthermore, one may realize the functionality of a single block in several circuit blocks, as desired. The choice of circuit implementation depends on various factors, such as particular design and performance specifications for a given implementation. Other modifications and alternative embodiments in addition to the embodiments in the disclosure will be apparent to persons of ordinary skill in the art. Accordingly, the disclosure teaches those skilled in the art the manner of carrying out the disclosed concepts according to exemplary embodiments, and is to be construed as illustrative only. Where applicable, the figures might or might not be drawn to scale, as persons of ordinary skill in the art will understand.

The particular forms and embodiments shown and described constitute merely exemplary embodiments. Persons skilled in the art may make various changes in the shape, size and arrangement of parts without departing from the scope of the disclosure. For example, persons skilled in the art may substitute equivalent elements for the elements illustrated and described. Moreover, persons skilled in the art may use certain features of the disclosed concepts independently of the use of other features, without departing from the scope of the disclosure.

1. An apparatus, comprising:
an impedance matching circuit for matching an impedance of a high quality factor (high-Q) antenna to an impedance of a radio-frequency (RF) circuit, the impedance matching network comprising:
a first reactive network; and
a second reactive network coupled in series with the first reactive network, wherein the second reactive network includes a reactive component realized by multiple reactive components so as to reduce sensitivity of the impedance matching network to component tolerances in the second reactive network.

2. The apparatus according to claim 1, wherein the reactive component realized by multiple reactive components comprises a capacitor realized by a plurality of series-coupled capacitors.

3. The apparatus according to claim 2, wherein the impedance matching circuit matches the impedance of an inductive high-Q antenna to the impedance of RF circuit.

4. The apparatus according to claim 1, wherein the reactive component realized by multiple reactive components comprises an inductor realized by a plurality of series-coupled inductors.

5. The apparatus according to claim 4, wherein the impedance matching circuit matches the impedance of a capacitive high-Q antenna to the impedance of RF circuit.

6. The apparatus according to claim 1, wherein the RF circuit comprises receive (RX) circuitry and/or transmit (TX) circuitry.

7. An apparatus, comprising:
an impedance matching circuit for matching an impedance of a high quality factor (high-Q) antenna to an impedance of a radio-frequency (RF) circuit, the impedance matching network comprising:
a reactive network comprising at least one reactive component; and
a resonant network coupled in shunt with the reactive network, wherein a reactance of the resonant tank as a function of frequency varies in an opposite manner of a reactance of the reactive network.

8. The apparatus according to claim 7, wherein the resonant network comprises an inductor coupled in parallel with a capacitor.

9. The apparatus according to claim 7, wherein the resonant network comprises a plurality of inductors coupled in parallel with a respective plurality of capacitors.

10. The apparatus according to claim 7, wherein the reactive network comprises at least one inductor.

11. The apparatus according to claim 7, wherein the reactive network comprises an inductor split into a plurality of inductors in order to reduce sensitivity of the impedance matching circuit to component tolerances.

12. The apparatus according to claim 7, wherein the reactive network comprises at least one capacitor.

13. The apparatus according to claim 7, wherein the reactive network comprises a capacitor split into a plurality of capacitors in order to reduce sensitivity of the impedance matching circuit to component tolerances.

14. An apparatus, comprising:
an impedance matching circuit for matching an impedance of a high quality factor (high-Q) antenna to an impedance of a radio-frequency (RF) circuit, the impedance matching network comprising:
a reactive network comprising at least one reactive component; and
a resonant network coupled in series with the reactive network, wherein a reactance of the resonant tank as a function of frequency varies in an opposite manner of a reactance of the reactive network.

15. The apparatus according to claim 14, wherein the resonant network comprises an inductor coupled in series with a capacitor.

16. The apparatus according to claim 14, wherein the resonant network comprises a plurality of inductors coupled in series with a respective plurality of capacitors.

17. The apparatus according to claim 14, wherein the reactive network comprises at least one inductor.

18. The apparatus according to claim 14, wherein the reactive network comprises an inductor split into a plurality of inductors in order to reduce sensitivity of the impedance matching circuit to component tolerances.

19. The apparatus according to claim 14, wherein the reactive network comprises at least one capacitor.

20. The apparatus according to claim 14, wherein the reactive network comprises a capacitor split into a plurality of capacitors in order to reduce sensitivity of the impedance matching circuit to component tolerances.
